(19) United States
(12) Patent Application Publication
(10) Pub. No.: US 2015/0065349 A1
(43) Pub. Date: Mar. 5, 2015

(54) SUPERCONDUCTING FILTER DEVICE, AND SUPERCONDUCTING FILTER ADJUSTING METHOD FOR SUPERCONDUCTING FILTER DEVICE

(71) Applicant: Kabushiki Kaisha Toshiba, Minato-ku (JP)

(72) Inventors: Mutsuki Yamazaki, Yokohama (JP); Kohei Nakayama, Kawasaki (JP); Noritsugu Shiokawa, Yokohama (JP); Tamio Kawaguchi, Kawasaki (JP); Hiroyuki Kayano, Fujisawa (JP)

(73) Assignee: Kabushiki Kaisha Toshiba, Minato-ku (JP)

(21) Appl. No.: 14/471,389

(22) Filed: Aug. 28, 2014

(30) Foreign Application Priority Data
Sep. 2, 2013 (JP) 2013-181567

(51) Int. Cl. H01P 1/20; H01L 39/02; H01L 39/10

(52) U.S. Cl. CPC H01P 1/20; H01L 39/10; H01L 39/02
USPC 505/210; 333/202

(57) ABSTRACT

A superconducting filter device of an embodiment includes: a high-frequency filter includes a superconducting element, and a dielectric member; and a drive tool configured to adjust a distance between the superconducting element and the dielectric member. The dielectric member and the drive tool take both a connection state and a separation state.

### CROSS-REFERENCE TO RELATED APPLICATION

This application is based upon and claims the benefit of priority from Japanese Patent Application No. 2013-181567, filed on Sep. 2, 2013; the entire contents of which are incorporated herein by reference.

### FIELD

Embodiments described herein relate to a superconducting filter device, and a superconducting filter adjusting method for a superconducting filter device.

### BACKGROUND

A superconducting element using a superconductor, such as a bandpass filter with GHz band, is formed such that a superconducting film is formed on both surfaces of a substrate made of a dielectric substance having small dielectric loss, such as sapphire or MgO, and the film on one surface is processed into a pattern in which plural resonators with a predetermined shape are arranged with a lithography technique. These resonators have to have the same resonance frequency. A resonance frequency is determined by a length of a resonator and a thickness of a substrate. Even if the length of each resonator is apparently the same, a degree of damage caused on a superconducting film during processing is different for each resonator. Therefore, it is difficult to make resonance frequencies exactly the same. Local difference in the thickness of the substrate makes it difficult to allow each resonator to have the same resonance frequency.

In view of this, a resonance frequency of each resonator is measured after the superconducting film is temporarily processed, and a part of the resonator is cut by laser, or a dielectric film is stacked on a part of or on the whole resonator, and the thickness of the dielectric film is adjusted, in order to make all resonators have the same resonance frequency. However, according to these methods, the frequency cannot be changed after once adjusted. In the former method, the length of the resonator is decreased by cutting the resonator. Therefore, the frequency cannot be decreased, although it can be increased. On the other hand, when the dielectric film is stacked, the effective length of the resonator increases. Therefore, the frequency can be decreased, but it cannot be increased. It is difficult to execute these methods when the superconducting film is in a superconducting state. Accordingly, it has been difficult to form a sharp-cut bandpass filter having a small band width and less loss.

### BRIEF DESCRIPTION OF THE DRAWINGS

FIG. 1 is a conceptual view of a high-frequency filter according to an embodiment;

FIG. 2 is a conceptual view illustrating a cross-section of the high-frequency filter according to the embodiment;

FIG. 3 is a conceptual view illustrating a top face of a resonator frequency adjusting member according to the embodiment;

FIG. 4 is a conceptual view illustrating a top face of a resonator frequency adjusting member according to the embodiment;

FIG. 5 is a conceptual view illustrating a cross-section of a superconducting high-frequency device according to an embodiment;

FIG. 6 is a conceptual view illustrating the cross-section of the superconducting high-frequency device according to the embodiment;

FIG. 7 is a flowchart illustrating an adjusting method of the superconducting high-frequency device according to the embodiment;

FIG. 8 is a flowchart illustrating an adjusting method of the superconducting high-frequency device according to the embodiment;

FIG. 9 is a conceptual view illustrating a cross-section of a superconducting high-frequency device according to an embodiment;

FIG. 10 is a conceptual view illustrating the cross-section of the superconducting high-frequency device according to the embodiment;

FIG. 11 is a conceptual view illustrating a cross-section of a superconducting high-frequency device according to an embodiment;

FIG. 12 is a conceptual view illustrating the cross-section of the superconducting high-frequency device according to the embodiment;

FIG. 13 is a conceptual view illustrating a cross-section of a superconducting high-frequency device according to an embodiment;

FIG. 14 is a conceptual view illustrating the cross-section of the superconducting high-frequency device according to the embodiment;

FIG. 15 is a conceptual view illustrating a cross-section of a superconducting high-frequency device according to an embodiment;

FIG. 16 is a conceptual view illustrating a cross-section of a superconducting high-frequency device according to an embodiment;

FIG. 17 is a conceptual view illustrating the cross-section of the superconducting high-frequency device according to the embodiment;

FIG. 18 is a conceptual view illustrating a cross-section of a superconducting high-frequency device according to an embodiment;

FIG. 19 is a conceptual view illustrating a cross-section of a component of the superconducting high-frequency device according to the embodiment; and

FIG. 20 is a conceptual view illustrating the cross-section of the superconducting high-frequency device according to the embodiment.

### DETAILED DESCRIPTION

A superconducting filter device of an embodiment includes: a high-frequency filter includes a superconducting element, and a dielectric member; and a drive tool configured to adjust a distance between the superconducting element and the dielectric member. The dielectric member and the drive tool take both a connection state and a separation state.

A superconducting filter device of an embodiment includes a high-frequency filter has a superconducting element and a dielectric member, a drive tool configured to adjust a distance between the superconducting element and the dielectric member, an vacuum chamber that stores the high-frequency filter and the drive tool in an vacuum space, and a drive source that drives the drive tool and that is provided outside the vacuum chamber. The drive tool and the vacuum chamber are not in contact with each other.

A superconducting filter adjusting method of an embodiment for a superconducting filter device includes a step of cooling the superconducting element to bring the superconducting element into a superconducting state a step of adjusting the distance between the dielectric member connected to the drive tool and the superconducting element, a step of evaluating a filter characteristic of the high-frequency filter, and a step of separating the dielectric member and the drive tool from each other. The superconducting filter device includes a high-frequency filter, which has a superconducting element and a dielectric member configured to adjust a filter characteristic of the superconducting element, and a drive tool that adjusts a distance between the superconducting element and the dielectric member.

### First Embodiment

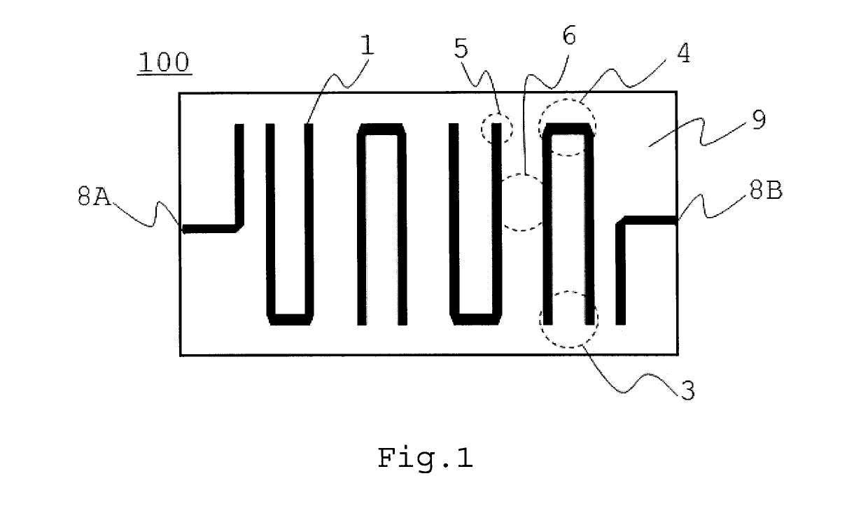

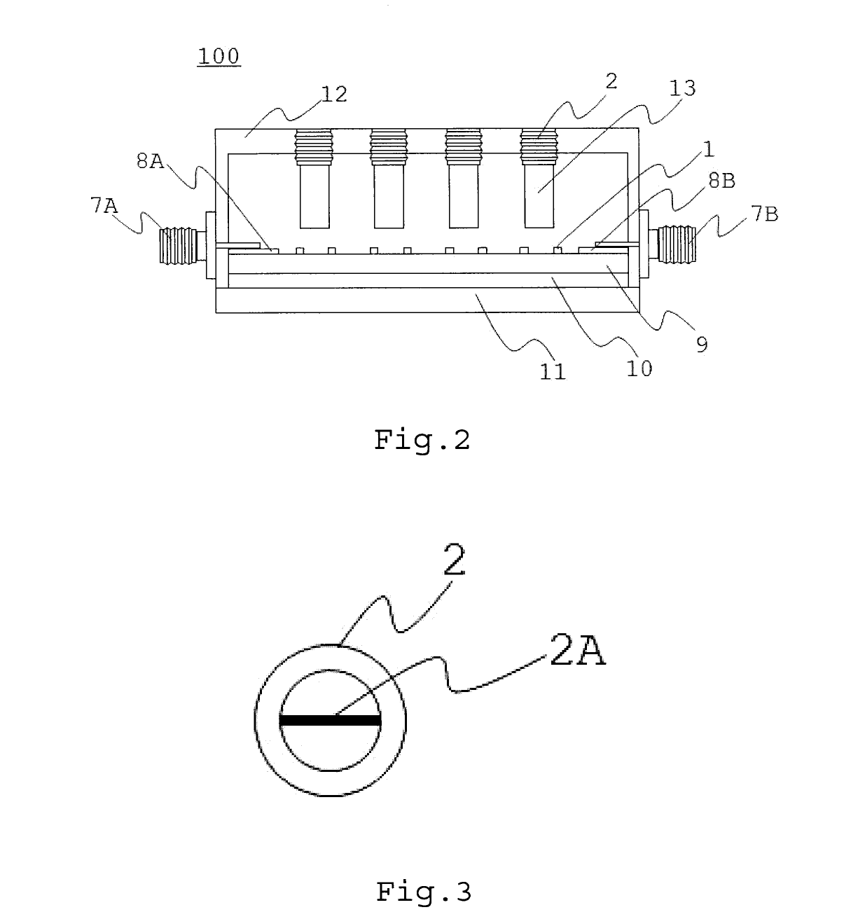

A high-frequency filter that is a resonator according to the embodiment includes a superconducting element and a container storing the superconducting element. The high-frequency filter 100 illustrated in a conceptual view in FIG. 1 includes a resonator pattern 1 and a power input/output point 8 on a dielectric substrate 9. A superconducting filter illustrated in a conceptual view in FIG. 2 has a cross-section different from the cross-section illustrated in the conceptual view in FIG. 1. The high-frequency filter 100 illustrated in the conceptual view in FIG. 2 includes a resonator pattern 1, male screws 2, high-frequency connectors 7, power input/output points 8, a low-loss dielectric substrate 9, a ground plane 10, a support member 11, a container 12, and a dielectric member.

The superconducting element in the high-frequency filter 100 is a superconducting member including the resonator pattern 1, the low-loss dielectric substrate 9, and the ground plane 10. The superconducting element is preferably cooled to an extremely-low temperature, such as 77 K or lower, at which the superconducting element is brought into a superconducting state.

The resonator pattern 1 is formed such that an oxide superconducting film, which is formed on the low-loss dielectric substrate 9 made of sapphire or MgO having less loss in a shortwave band to a millimeter band and contains one or more elements selected from Y, Ba, Cu, La, Ta, Bi, Sr, Ca, and Pb, is formed into a desired shape. A known lithography technique can be employed for forming the film into the desired shape.

The ground plane 10 made of an oxide superconducting film containing one or more elements selected from Y, Ba, Cu, La, Ta, Bi, Sr, Ca, and Pb is formed on the surface of the low-loss dielectric substrate 9 opposite to the surface on which the resonator pattern is formed.

The support member 11 for supporting the superconducting element is provided on the surface of the ground plane 10, opposite to the surface on which the low-loss dielectric substrate 9 is formed, of the superconducting element. The support member 11 is preferably made of a material having low specific resistance and high thermal conductivity, such as Cu or Al.

The high-frequency connector 7 is mounted to the support member 11 serving as an input/output terminal for high-frequency power. The high-frequency connector 7 is a conductive terminal for connecting the inside and the outside of the container of the high-frequency filter 100. High-frequency power is inputted from the high-frequency connector 7A. The inputted high-frequency power passes through the power input/output terminal 8A, and when it passes through the resonator pattern 1, power in a frequency band other than a desired frequency band is attenuated. The high-frequency power passing through the resonator pattern 1 passes through the input/output terminal 8B, and is outputted from the high-frequency connector 7B.

The container 12 encloses the high-frequency filter 100. From the viewpoint of cooling the high-frequency filter 100 to an extremely-low temperature, the container 12 is preferably made of a material having low specific resistance and high thermal conductivity, such as Cu or Al. When the container 12 is insufficiently cooled, the temperature on the surface of the superconducting film increases due to radiation, whereby a Q value decreases. Considering this situation, the container 12 is preferably made of a material having high thermal conductivity. A female screw into which the male screw 2 is threaded is formed on the container 12.

The low-loss dielectric member 13 adjusts a resonance frequency depending upon the distance between the resonator pattern 1 and the low-loss dielectric member 13. The dielectric member is provided on the male screw 2 at the side of the resonator pattern 1. The distance between the low-loss dielectric member 13 and the resonator pattern 1 can be adjusted by rotating the male screw 2. The low-loss dielectric member 13 is made of a material having small dielectric loss, such as sapphire, sintered alumina, or MgO. Like the container 12, the male screw 2 is preferably made of a material having small specific resistance and high thermal conductivity.

As for the adjustment of the high-frequency characteristic, the resonance frequency becomes low when the tip end of the columnar low-loss dielectric member 13 approaches the resonator of the superconducting element, for example. The resonance frequency varies more greatly in the case where the low-loss dielectric member 13 approaches an end 3 of the resonator pattern 1 than in the case where the low-loss dielectric member 13 approaches a vicinity of a center 4 of the length of the resonator pattern 1. Even when the distance between the low-loss dielectric member 13 and the resonator pattern 1 is changed only at one end 5, the resonance frequency is changed. When the low-loss dielectric member 13 approaches a portion 6 between the resonators, a bond between the resonators is strengthened. A bandpass filter that is one of superconducting elements is formed by combining plural resonators and transmits a specific band with low loss. This is attained by allowing each resonator to have the same resonance frequency and to have a predetermined bond.

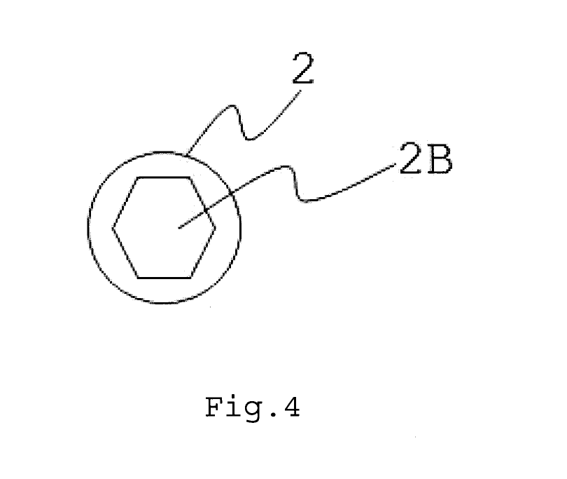

FIGS. 3 and 4 are conceptual top views of the male screw 2. The high-frequency filter 100 according to the embodiment can adjust the resonance frequency characteristic by rotating the male screw 2. When a mechanism or a device for rotating the male screw 2 is connected to the male screw 2, vibration or heat from the outside is likely to affect the superconducting filter. In view of this, a thread that can be connected to and separated from a device for rotating the male screw 2 is formed on the top of the male screw 2 in the present embodiment. The thread preferably has a shape suitable for rotation, such as a straight slot shape or hexagonal shape. Examples of the shape suitable for rotation include a shape having many symmetry axes, considering that the male screw 2 is easy to be connected to a drive tool for rotating the male screw 2. For example, a regular triangle has three symmetry axes. The more the number of sides increases such as a square or regular hexagon, the more the number of symmetry axes increases, which means the meshed position increases, thus preferable. However, the number of the symmetry axes has to be finite, and a circle having infinite symmetry axes is excluded. The one having a small backlash is preferable for the male screw 2, since it can keep the resonance frequency characteristic.

The low-loss dielectric member 13 is mounted to the male screw 2 having a small backlash. The male screw 2 is threaded to the female screw on the outer container 12. According to this structure, the distance between the superconducting element and the low-loss dielectric member 13 can be changed by rotating the male screw, whereby the high-frequency characteristic of the superconducting element can be changed. As illustrated in the conceptual view in FIG. 3, a groove that is meshed with a straight slot screwdriver is formed on the tip end of the male screw 2. Alternatively, a hexagonal recess for a hexagonal wrench is formed as illustrated in the conceptual view in FIG. 4. The shape having many symmetrical axes can realize a smooth connection between the drive tool and the low-loss dielectric member 13. For example, a regular triangle has three symmetry axes. The more the number of sides increases such as a square or regular hexagon, the more the number of symmetry axes increases, which means the meshed position increases, thus preferable. Therefore, the male screw 2 is processed to have a shape having two or more symmetry axes, more preferably three or more symmetry axes, and most preferably four or more symmetry axes. However, the number of the symmetry axes has to be finite, and a circle having infinite symmetry axes is excluded. As for the adjustment of the high-frequency characteristic, the resonance frequency becomes low when the tip end of the columnar low-loss dielectric member 13 approaches the resonator that is the superconducting element, for example. The resonance frequency varies more greatly in the case where the low-loss dielectric member 13 approaches the end 3 of the resonator than in the case where the low-loss dielectric member 13 approaches a vicinity of the center 4 of the length of the resonator. The resonance frequency is also changed even if the low-loss dielectric member 13 approaches only one end 5. When the low-loss dielectric member 13 approaches the portion 6 between the resonators, a bond between the resonators is strengthened. A bandpass filter that is one of superconducting elements is formed by combining plural resonators and transmits a specific band with low loss. This is attained by allowing each resonator to have the same resonance frequency and to have a predetermined bond.

### Second Embodiment

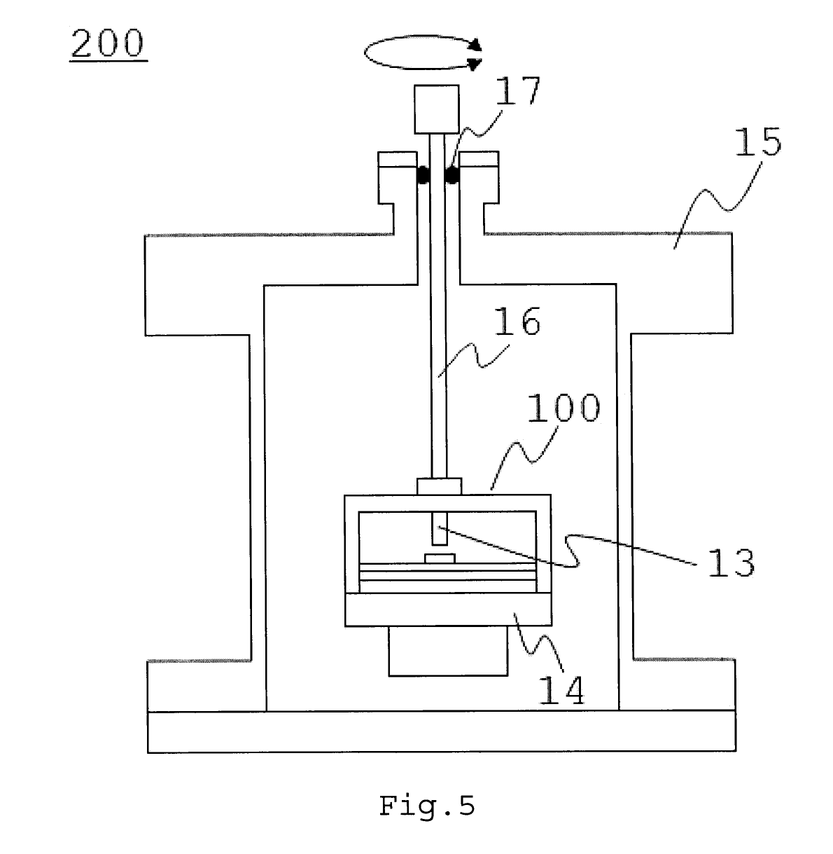

A superconducting filter device according to an embodiment includes a high-frequency filter, and a drive tool that adjusts a distance between a superconducting element and a dielectric member of the high-frequency filter. The dielectric member and the drive tool can be connected to each other and separated from each other. FIG. 5 illustrates a conceptual view of a superconducting filter device 200 according to the embodiment. The superconducting filter device 200 in FIG. 5 includes a high-frequency filter 100, a cold head 14, a container 15, a drive tool 16, and an O-ring 17. The superconducting filter device 200 in FIG. 5 can reduce pressure in the container 15 and in the high-frequency filter 100 by an exhaust device not illustrated.

The high-frequency filter 100 according to the first embodiment can be used for the high-frequency filter 100. The high-frequency filter 100 is held on the cold head 14 cooled to a low temperature of 77 K or lower by a freezer not illustrated. The low-loss dielectric member 13 of the high-frequency filter 100 is connected to the drive tool 16 via the male screw 2. In the embodiment, the state in which the low-loss dielectric member 13 and the drive tool 16 are indirectly connected or separated via the male screw 2 and the state in which the low-loss dielectric member 13 and the drive tool 16 are directly connected or separated are synonymously regarded from the viewpoint of adjusting the distance between the low-loss dielectric member 13 and the superconducting element.

In the structure of the embodiment, the drive tool 16 is a first rotation axis that can adjust the distance between the low-loss dielectric member 13 and the superconducting element by rotating the male screw 2 through an operation of a tip end of the drive tool 16 outside the container 15. A drive source having power for rotating the drive tool 16 such as a motor is provided on the tip end of the drive tool 16 outside the container 15. The drive source includes a mechanism for rotating the drive tool. The drive source may have a drive source for connecting the drive tool 16 and the low-loss dielectric member 13 or for separating the drive tool 16 from the low-loss dielectric member 13. Alternatively, the drive tool 16 and the low-loss dielectric member 13 may be connected to or separated from each other by a drive source not illustrated. The embodiment employs a mechanism for rotating the male screw 2 connected to the low-loss dielectric member 13. The high-frequency filter 100 is not limited to this mechanism. Any structures other than the structure described in the embodiment can be used, so long as they can adjust the distance between the low-loss dielectric member 13 and the superconducting element. The drive tool 16 is arranged to penetrate a hole formed on a part of the container 15. The axis of the drive tool 16 penetrating the container 15 is sealed by the O-ring 17 to keep the vacuum state in the container 15. Since the axis is sealed by the O-ring 17, the container 15 keeps vacuum state, so that the drive tool 16 can rotate. The O-ring 17 can prevent air and heat from entering the container 15.

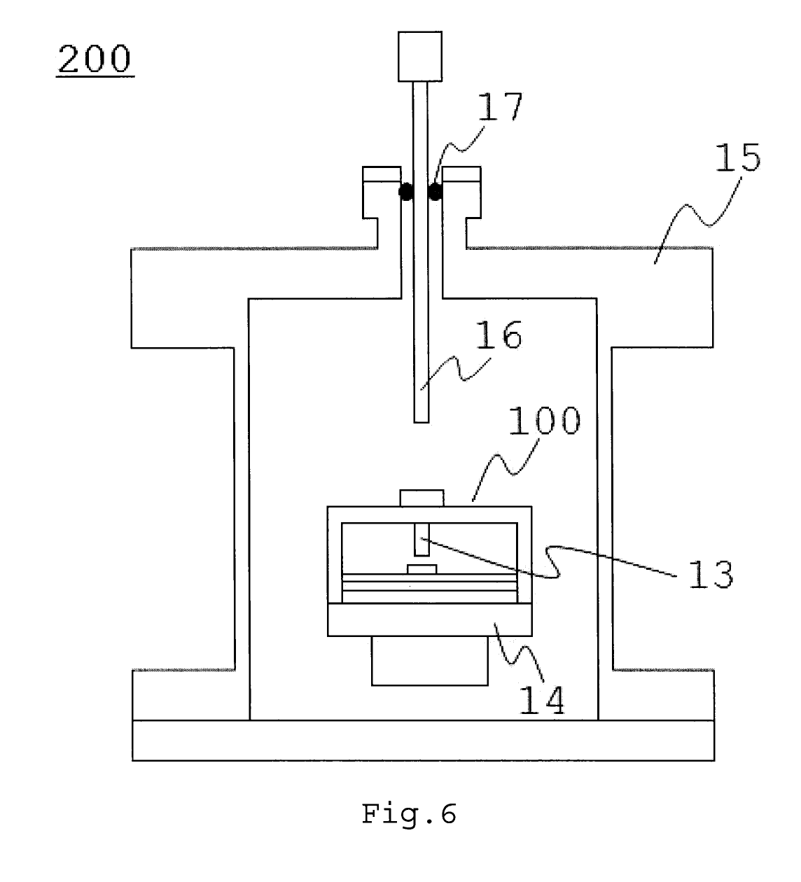

After the filter is adjusted to have a desired frequency characteristic by adjusting the distance between the low-loss dielectric member 13 and the superconducting element, the drive tool 16 can be separated from the dielectric member 13. As illustrated in a conceptual view in FIG. 6, the drive tool 16 is separated by moving the drive tool in the axial direction of the drive tool 16 in the conceptual view in FIG. 5. Since the vacuum state of the drive tool 16 and the container 15 is maintained by using the O-ring, the vacuum state in the container 15 can be maintained by the O-ring 17 even if the drive tool 16 is separated from the low-loss dielectric member 13. In the state in which the drive tool 16 is separated from the low-loss dielectric member 13 as illustrated in the conceptual view in FIG. 6, heat or vibration from the outside of the container 15 is not transmitted to the high-frequency filter 100 from the drive tool 16. Heat or vibration from the outside of the container 15 causes variation in the frequency characteristic of the high-frequency filter 100. When the frequency characteristic of the high-frequency filter 100 varies from the desired characteristic, the frequency characteristic can be adjusted again by connecting the drive tool 16 and the low-loss dielectric member 13 via the male screw 2.

### Third Embodiment

The third embodiment describes a high-frequency characteristic adjusting method of a high-frequency superconducting filter device including a high-frequency filter, which has a superconducting element and a dielectric member for adjusting a filter characteristic of the superconducting element, and a drive tool for adjusting a distance between the superconducting element and the dielectric member, the method including a step of cooling the superconducting element; a step of adjusting the distance between the dielectric member connected to the drive tool and the superconducting element; a step of evaluating the filter characteristic of the high-frequency filter; and a step of separating the dielectric member and the drive tool.

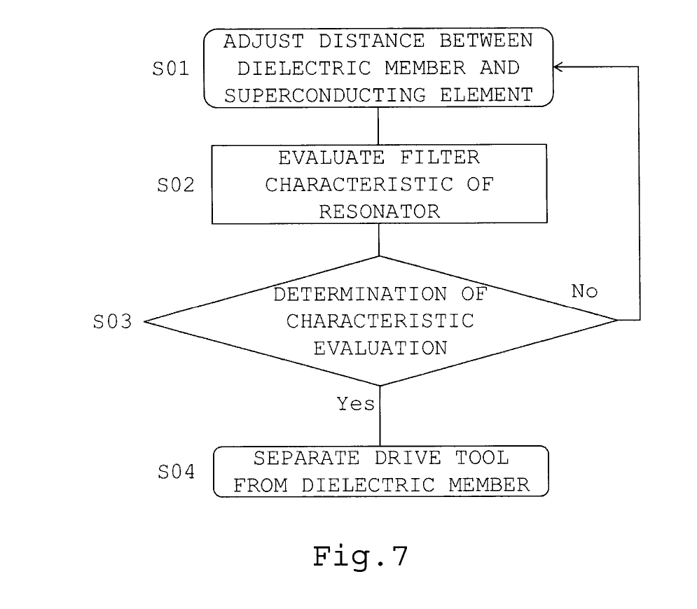

The third embodiment describes the adjusting method of a high-frequency characteristic illustrated in a flowchart in FIG. 7 by using the superconducting filter device 200 according to the second embodiment illustrated in the conceptual views in FIGS. 5 and 6, for example.

Step 1 (S01)

A high-frequency characteristic is adjusted in the state in which the male screw 2 connected to the low-loss dielectric member 13 and the drive tool 16 are connected as illustrated in the conceptual view in FIG. 5. The superconducting element in the high-frequency filter 100 is preliminarily cooled with a freezer, not illustrated, to 77 K or lower, for example, by which the superconducting element is brought into a superconducting state. The container 12 and the container 15 are evacuated by a pressure reducing device not illustrated. The cooling temperature is different depending upon a superconducting element. The pressure in the container 12 and the pressure in the container 15 are different depending upon a superconducting element. The drive tool 16 is rotated to change the threaded depth of the male screw 2 into the container 12, whereby the distance between the low-loss dielectric member 13 and the superconducting element is adjusted.

Step 2 (S02)

An unillustrated device that can evaluate a frequency characteristic, such as a network analyzer, is connected to the high-frequency connector 7 to evaluate the high-frequency characteristic of the high-frequency filter 100.

Step 3 (S03)

It is determined whether the high-frequency characteristic of the high-frequency filter 100 obtained as a result of the evaluation is a desired characteristic or not. When the obtained characteristic is the desired characteristic, the process proceeds to step 4. When the obtained characteristic is not the desired characteristic, the process returns to step 1 to again adjust the distance between the low-loss dielectric member 13 and the superconducting element.

Step 4 (S04)

As illustrated in the conceptual view in FIG. 6, the drive tool 16 is moved in the axial direction to separate the drive tool 16 and the low-loss dielectric member 13 from each other.

According to the adjusting method of a high-frequency characteristic in the embodiment, a high-frequency characteristic is adjusted, and the drive tool used for the adjustment can physically be separated from the high-frequency filter, in the superconducting state. The drive tool is likely to transmit heat or vibration from the outside of the superconducting filter device. Therefore, the state in which the drive tool keeps on physically being connected to the high-frequency filter is not preferable from the viewpoint of maintaining the high-frequency characteristic. In the embodiment, the high-frequency filter and the drive tool are separated from each other after the adjustment of the high-frequency characteristic, whereby the stability of the high-frequency characteristic is enhanced. After the adjustment of the high-frequency characteristic, the high-frequency filter can be transferred to another container having higher vacuum state without having a drive tool, and can be used as a superconducting filter device.

### Fourth Embodiment

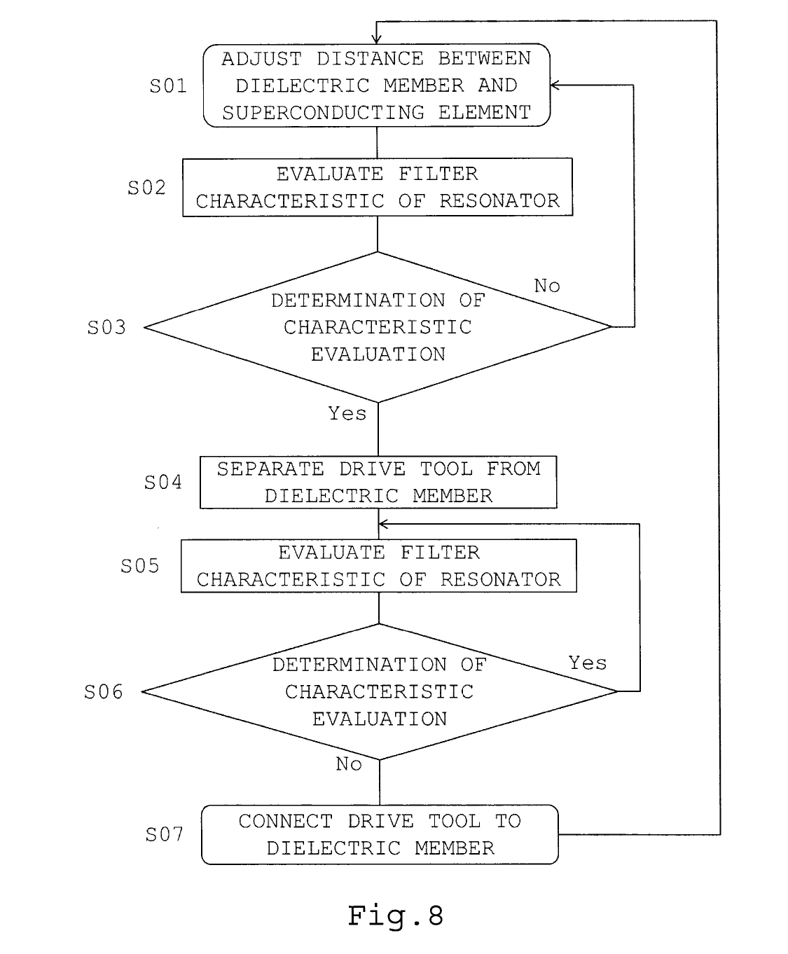

The fourth embodiment describes an adjusting method of a high-frequency characteristic to which another step is added to the method according to the third embodiment, by using the superconducting filter device according to the second embodiment illustrated in the conceptual views in FIGS. 5 and 6, for example. FIG. 8 illustrates the adjusting method according to the fourth embodiment.

In the adjusting method according to the fourth embodiment, the step 1 to the step 4 are the same as those in the third embodiment. Therefore, the description of the same processes will not be repeated.

Step 5 (S05)

It is determined whether or not the high-frequency filter 100 keeps a desired high-frequency characteristic. The high-frequency characteristic might be changed by external influence due to a long-term use. When the high-frequency characteristic is changed, or when the high-frequency characteristic is likely to be changed, the evaluation as in step 2 is carried out at any timing.

Step 6 (S06)

It is determined whether the high-frequency characteristic of the high-frequency filter 100 obtained as a result of the evaluation is a desired characteristic or not. When the obtained characteristic is the desired characteristic, the process returns to step 5 at necessary timing. When the obtained characteristic is not the desired characteristic, the process proceeds to step 7.

Step 7 (S07)

When the high-frequency filter 100 does not have the desired characteristic, the distance between the low-loss dielectric member 13 and the superconducting element has to be adjusted again. The drive tool 16 and the low-loss dielectric member 13 are connected, and then, the process returns to step 1.

According to the adjusting method of a high-frequency characteristic in the embodiment, a high-frequency characteristic is adjusted, and the drive tool used for the adjustment can physically be separated from the high-frequency filter, in the superconducting state, as in the third embodiment. Even if the adjusted high-frequency characteristic is changed, the high-frequency characteristic can be adjusted again by connecting the drive tool 16 to the low-loss dielectric member 13.

In the third and fourth embodiments, the adjustment of a high-frequency characteristic can be automated by using a computer. For automation, each step can be controlled with software or hardware by using arithmetic elements such as a microcomputer or FPGA (Field Programmable Gate Array). The device that automatically adjusts a high-frequency characteristic by using a computer can be implemented as a high-frequency characteristic adjusting system.

The third and fourth embodiments describe the adjusting method for the device according to the second embodiment. However, the described adjusting method or the adjusting system can similarly adjust a high-frequency characteristic in the embodiments described below.

### Fifth Embodiment

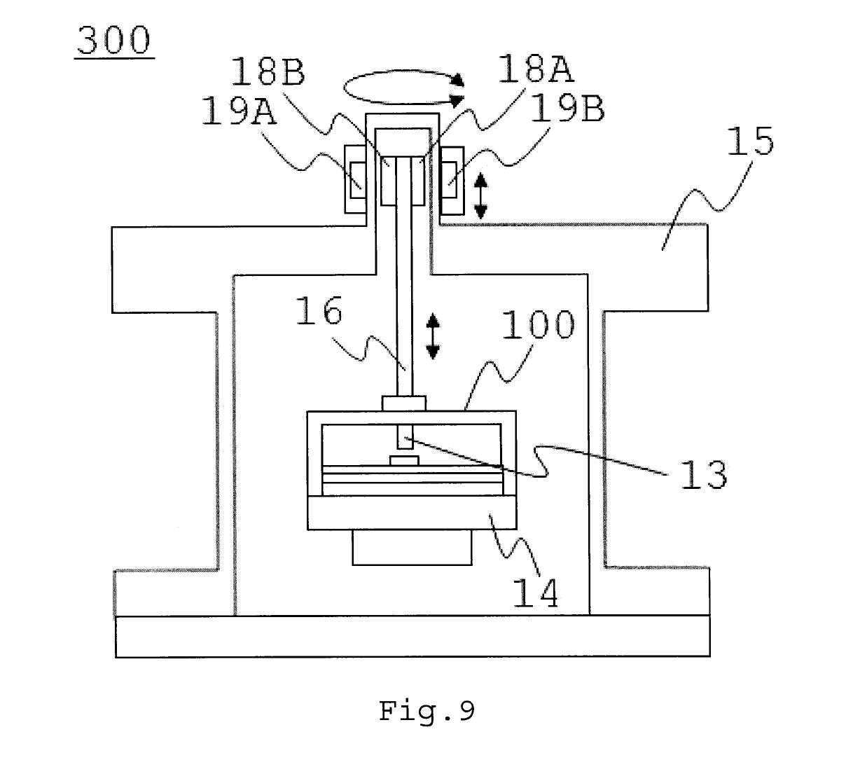

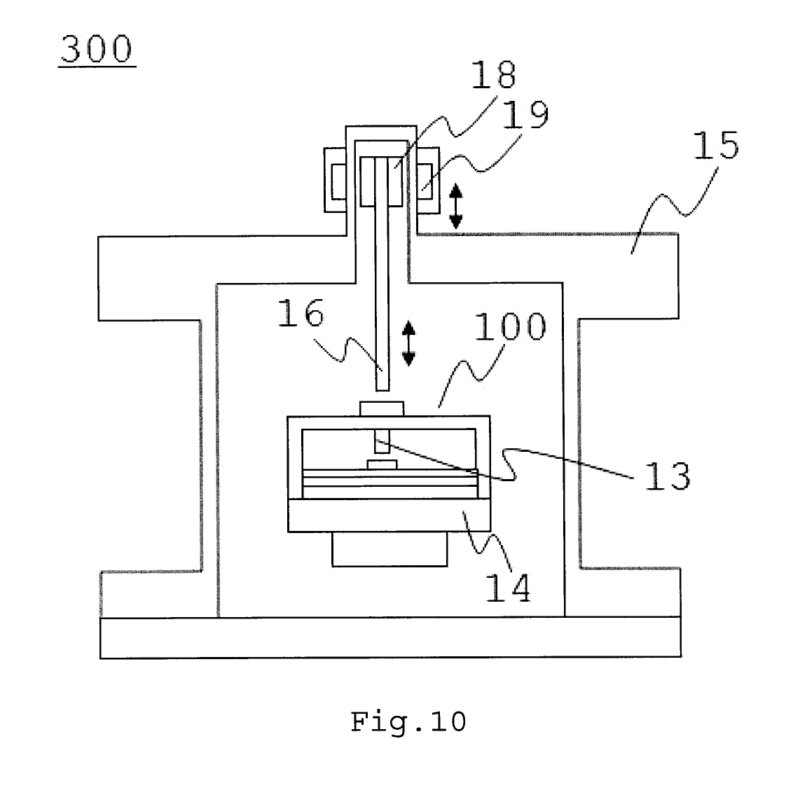

FIG. 9 is a conceptual view illustrating a superconducting filter device 300 in which the drive source for the drive tool 16 is replaced by an internal magnet 18 and an external magnet 19. The configuration of the superconducting filter device other than the drive source for the drive tool 16 is the same as that in the second embodiment, so that the description will not be repeated. FIG. 10 is a conceptual view illustrating that the drive tool 16 and the low-loss dielectric member 13 are separated from each other.

The internal magnet 18 is mounted on a top of an axis of the drive tool 16. The internal magnet 18 includes a north pole 18A and a south pole 18B. The external magnet 19 is mounted on the exterior of the container 15 with the level same as the internal magnet 18. The external magnet 19 has a north pole 19A and a south pole 19B. When the external magnet 19 is rotated, the internal magnet 18 follows the rotation of the external magnet 19 due to magnetic force. The distance between the internal magnet 18 and the external magnet 19 can be adjusted, according to need, depending upon magnetic force or required rotation drive force. As illustrated in the conceptual view in FIG. 10, when the external magnet 19 is moved upward, the drive tool 16 can be separated from the low-loss dielectric member 13. When the external magnet 19 is moved downward, the drive tool 16 and the low-loss dielectric member 13, which are separated from each other, can be connected to each other.

The fifth embodiment describes the superconducting filter device 300 in which the drive source is not physically in contact with the drive tool 16. Heat is only transferred to the drive tool used for the adjustment, so that heat transfer is reduced. Therefore, variation in the characteristic caused by the temperature rise during the adjustment can be prevented. This configuration can realize a stable operation of the superconducting filter device. The adjusting method and the adjusting system are similar to those in the third and fourth embodiments.

### Sixth Embodiment

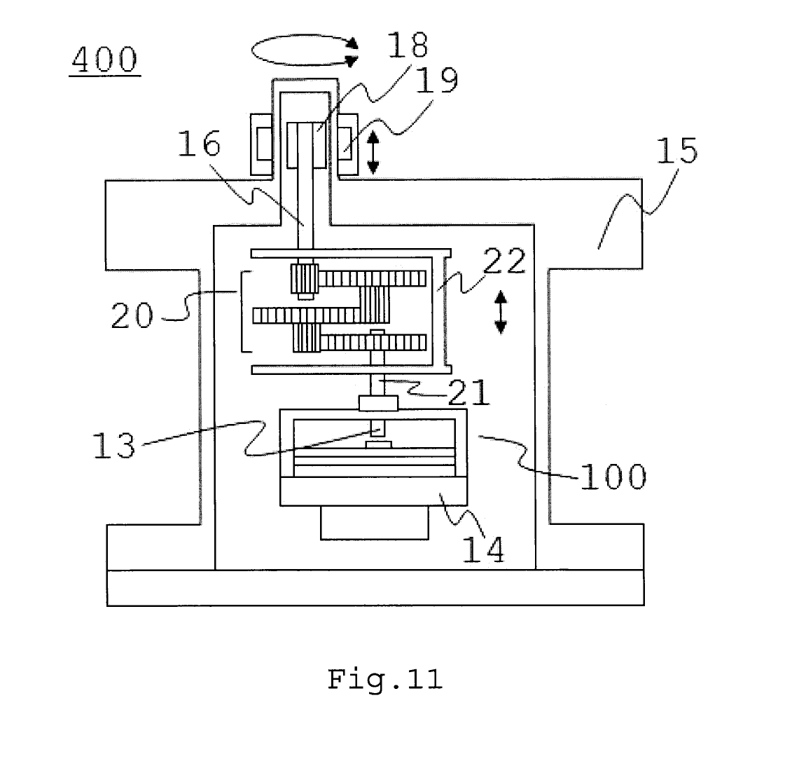

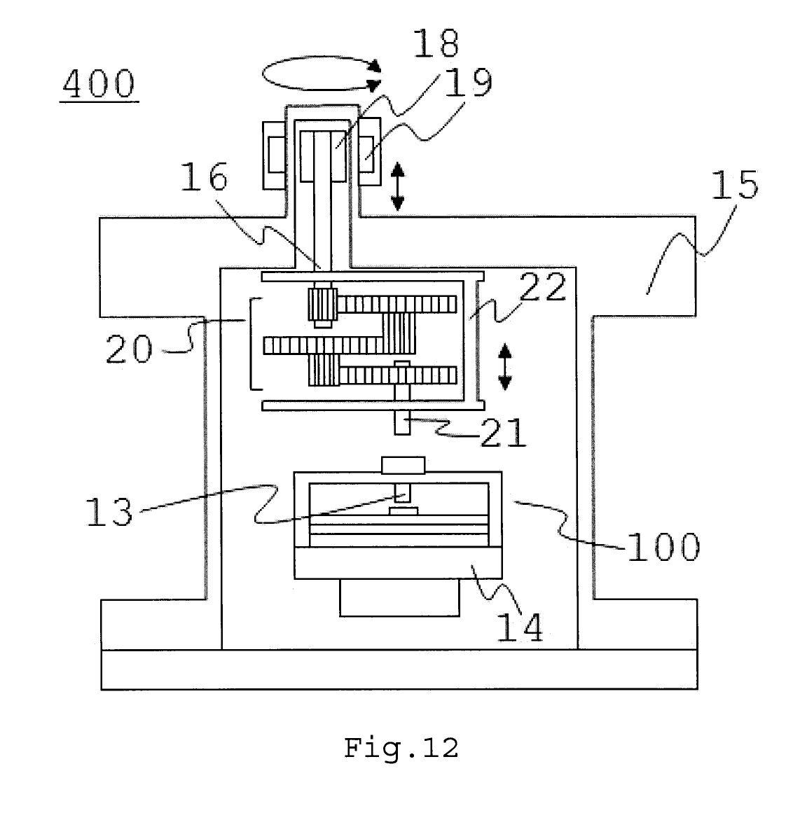

FIG. 11 is a conceptual view illustrating a superconducting filter device 400. In the superconducting filter device 400, a first rotation axis 16, a gear 20, and a second rotation axis 21 are used as the drive tool, wherein the second rotation axis 21 is used as a member connected to the low-loss dielectric member 13. A fixing member 22 for holding the gear 20 is also provided. The configuration of the superconducting filter device other than the drive tool according to the sixth embodiment is the same as that in the fifth embodiment, so that the description will not be repeated. FIG. 12 is a conceptual view illustrating that the drive tool (the first rotation axis 16, the gear 20, and the second rotation axis 21) is separated from the low-loss dielectric member 13.

In the sixth embodiment, the drive tool adjusts the height of the low-loss dielectric member 13 via the first rotation axis 16, the gear 20, and the second rotation axis 21. An internal magnet 18 is provided on the leading end of the first rotation axis 16. The other end of the first rotation axis 16 is connected to the gear 20. The gear 20 is formed by combining plural gear wheels, each having a different number of teeth. The rotation of the gear 20 becomes drive force for rotating the low-loss dielectric member 13 via the second rotation axis 21. In this embodiment, plural gear wheels are combined. Therefore, torque of the rotation axis 21 can be increased, even if magnetic force of the internal magnet 18 and the external magnet 19 is small. When the gear ratio of the gear 20 is increased, torque of the second rotation axis 21 can be increased, whereby the number of rotations of the second rotation axis 21 can be reduced. The reduction in the number of rotations of the second rotation axis 21 can facilitate a fine adjustment in heights of the low-loss dielectric member 13 and the superconducting element.

The gear 20 is fixed by the fixing member 22 so as not to be shifted. When the external magnet 19 is moved upward, the drive tool can be separated from the low-loss dielectric member 13 as illustrated in the conceptual view in FIG. 12. When the external magnet 19 is moved downward, the drive tool and the low-loss dielectric member 13, which are separated from each other, can be connected to each other.

In the sixth embodiment, the number of rotations and torque can be adjusted to be desired values by the configuration other than the drive source. Thus, the sixth embodiment is suitable for finely adjusting the distance between the low-loss dielectric member 13 and the superconducting element. The position of the drive tool and the position of the low-loss dielectric member 13 can be shifted by the gear 20. Therefore, these positions can be adjusted, when spatial limitation is imposed inside and outside the container 15. The adjusting method and the adjusting system are similar to those in the third and fourth embodiments.

### Seventh Embodiment

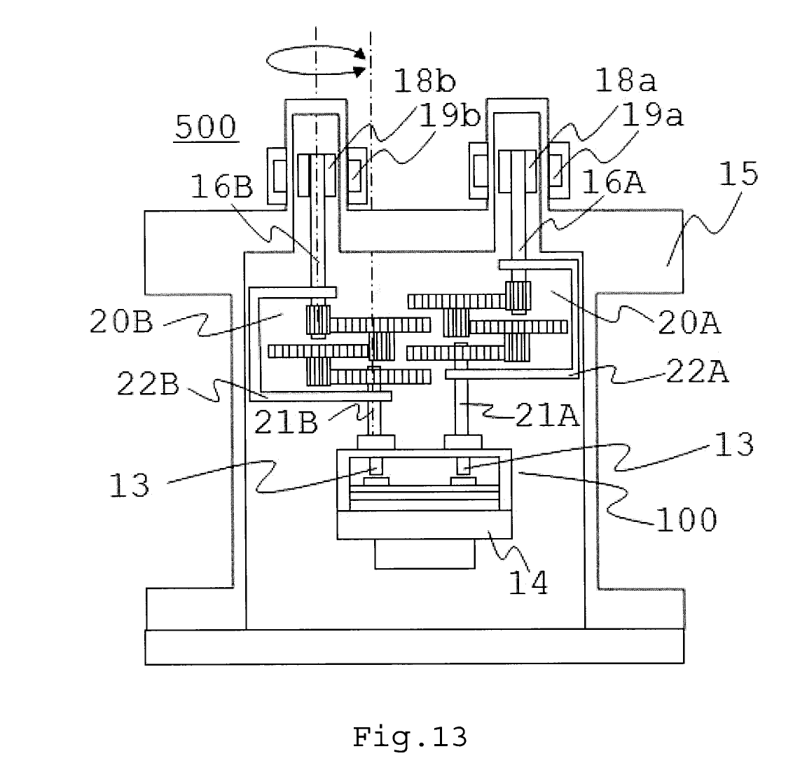

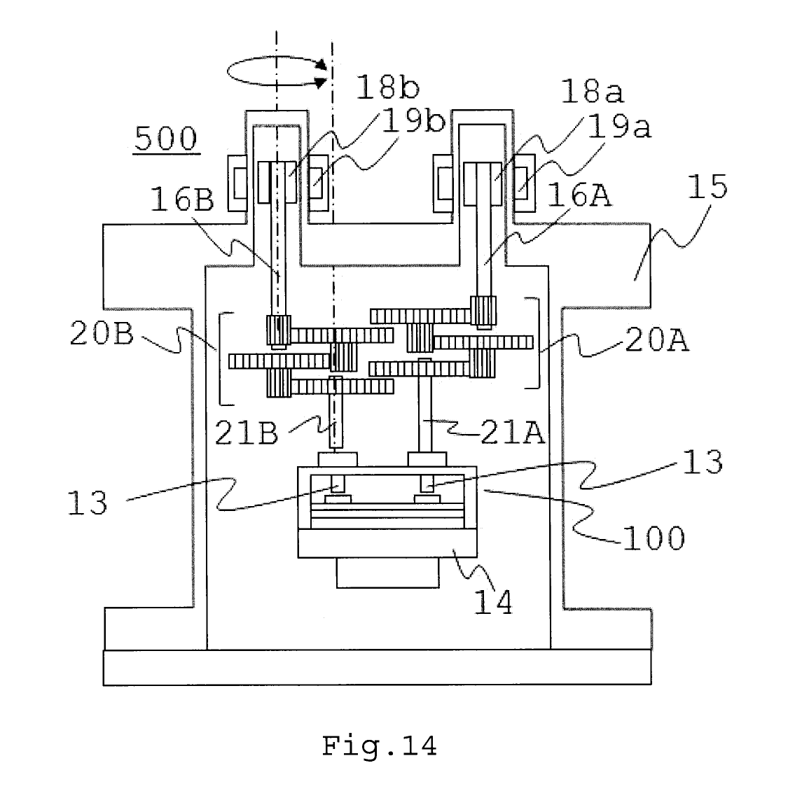

FIG. 13 is a superconducting filter device 500 that includes a high-frequency filter 100 having plural low-loss dielectric members 13, and plural drive tools for adjusting the distance between each of the low-loss dielectric members 13 and the superconducting element described in the sixth embodiment. The configuration of the superconducting filter device according to the seventh embodiment same as that in the sixth embodiment will not be described again. FIG. 14 is a conceptual view illustrating that the drive tool and the low-loss dielectric member 13 are separated from each other. The right drive tool in FIGS. 13 and 14 are identified by 16A and the left drive tool in FIGS. 13 and 14 are identified by 16B.

In the present embodiment, the rotation center of the external magnet 19 and the rotation center of the second rotation axis 21 can be shifted. When the rotation center of the external magnet and the rotation center of the rotation axis are the same in the case where the low-loss dielectric members 13 are adjacent to each other in the superconducting filter device including plural members for adjusting the distance between the low-loss dielectric member 13 and the superconducting element, the external magnets are consecutively provided. The external magnets adjacent to each other are susceptible to magnetic force. Therefore, when one of the external magnets is rotated, the other unintended external magnet is likely to be rotated. In the present embodiment, the rotation center of the external magnet 19 and the rotation center of the second rotation axis 21 are shifted. With this configuration, the distance between the external magnets 19a and 19b can be larger than the distance between the low-loss dielectric members 13. The magnetic force between the separated external magnets 19a and 19b becomes weak, and each magnet can easily adjust the high-frequency characteristic independently.

In the device having the plural drive tools, the positional adjustment is carried out such that the drive tool for the positional adjustment is connected to the dielectric member, while the drive tool not used for the positional adjustment is separated from the low-loss dielectric member 13. When the external magnet 19b not involved with the positional adjustment is moved upward as illustrated in the conceptual view in FIG. 14, the left drive tool is separated from the low-loss dielectric member 13. Even if the other external magnet 19a is rotated later, and the adjacent external magnet 19b moves with the magnet 19a because of strong magnetic force between the external magnets 19a and 19b, the distance between the low-loss dielectric member 13 and the superconducting element at the left side in FIG. 14 is not changed, since the drive tool for the magnet 19b and the low-loss dielectric member 13 are separated from each other. Heat is only transferred to the drive tool used for the adjustment, so that heat transfer is reduced. Therefore, variation in the characteristic caused by the temperature rise during the adjustment can be prevented.

The device in the embodiment can be tilted at an angle of 90° or almost 90° for use. The gravitational direction of the drive tool can be shifted toward the vertical direction from the side of the high-frequency filter 100 by tilting the device. In this case, the drive tool is fixed to a position separated from the low-loss dielectric member 13, even if the external magnet 19 is not fixed, or is removed. Accordingly, all independent drive tools can independently be driven by only one external magnet 19.

In the present embodiment, each of the plural low-loss dielectric members 13 can independently be adjusted, whether the magnetic force of the external magnet 19 is strong or not. Since the gear 20 is used, the plural drive tools can be overlapped in the container 15. Therefore, the superconducting filter device 500 can be downsized, even if the device has a large drive tool. The plural drive tools can independently be driven, and the adjusting method and the adjusting system are similar to those in the third and fourth embodiments. When the plural drive tools are adjusted in conjunction with one another, the adjusting method and the adjusting system are also similar to those in the third and fourth embodiments.

### Eighth Embodiment

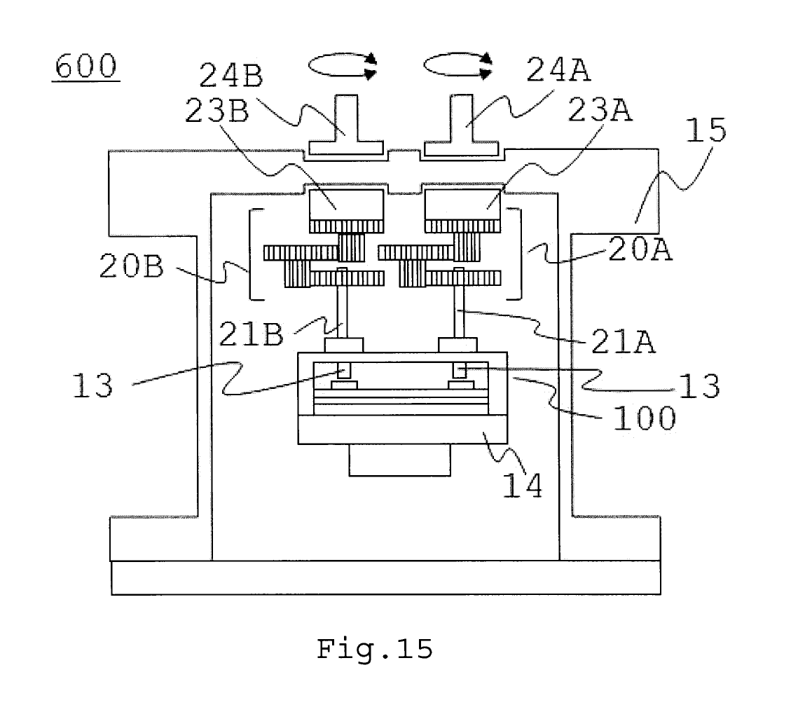

FIG. 15 is a superconducting filter device 600 in which an internal magnet 23 is directly provided to a gear 20 of a drive tool, and an external magnet 24 is arranged across a wall face of a container 15. The configuration of the superconducting filter device 600 according to the eighth embodiment same as that in the seventh embodiment will not be described again.

The conceptual view in FIG. 15 illustrates the superconducting filter device 600 in which the internal magnet 23 is directly provided on the surface of the gear wheel of the gear 20, and this internal magnet 23 is rotated by the external magnet 24. The internal magnet 23 is not in contact with the vacuum chamber 15. Therefore, heat transfer is small. The internal face or external face of the container 15 is cut with an area larger than the diameter of the internal magnet 23 or the external magnet 24, in order to reduce the thickness of the wall face of the container 15 where the magnet is provided. Since the wall face is thin, the magnetic force of the internal magnet 23 and the external magnet 24 becomes large. Therefore, torque can further be increased by the increase in torque of the gear 20 as well as by the combination of the magnets in the present embodiment.

### Ninth Embodiment

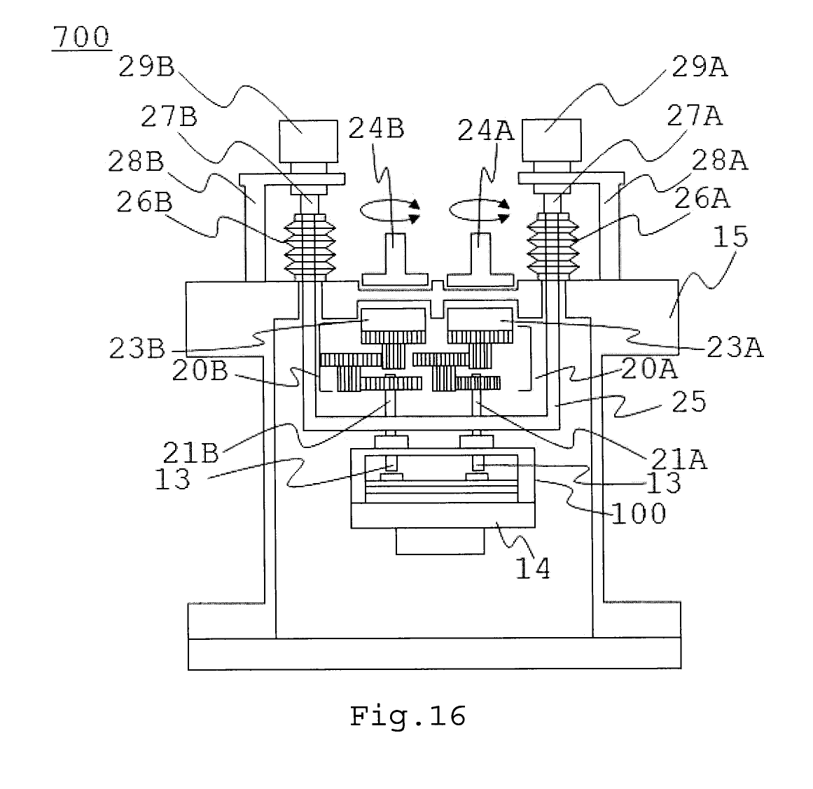

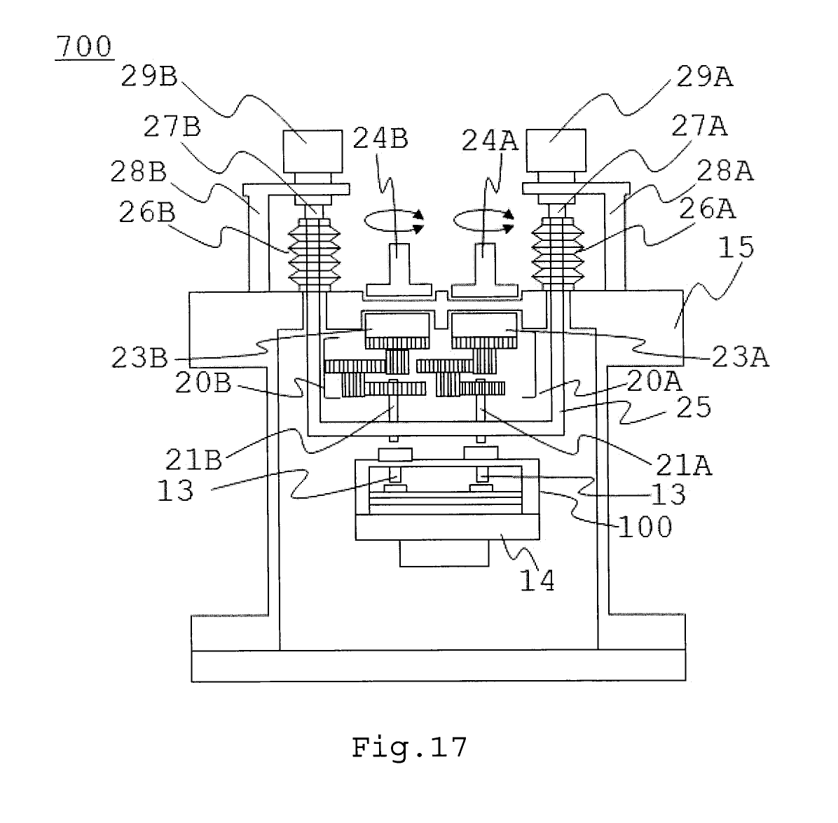

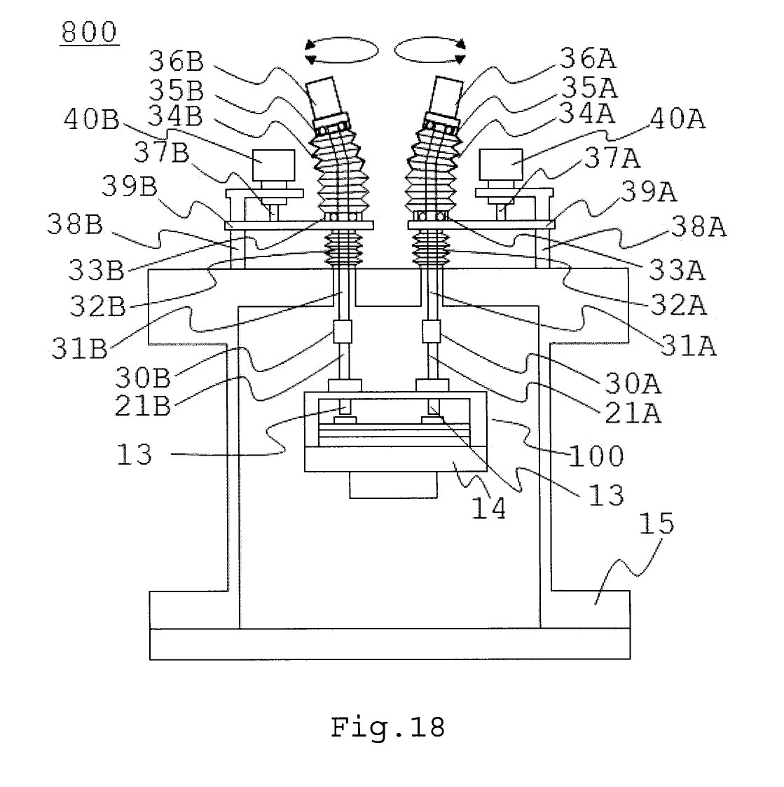

FIG. 16 is a conceptual view illustrating a superconducting filter device 700 formed by adding bellows, which adjusts the height of the drive tool, to the superconducting filter device 600 according to the eighth embodiment. The configuration of the superconducting filter device according to the ninth embodiment same as that in the eighth embodiment will not be described again. FIG. 17 is a conceptual view illustrating that the drive tool and the low-loss dielectric member 13 are separated from each other.

In the superconducting filter device 700 illustrated in FIG. 16, plural drive tools for adjusting the plural low-loss dielectric members 13 are supported by a plate 25. The plate 25 is connected to a linear motion device including a bellows 26, a support rod 27, a fixing tool 28, and a knob 29. The linear motion device can move the plate 25 and the drive tool supported by the plate 25 in the vertical direction. The container 15 and the bellows 26 can form an elastically deformable vacuum wall that can maintain a pressure-reducing state of 10² Pa or less, preferably 10⁻⁴ Pa or less. For example, the bellows 26 is welded to cover a through-hole formed on a top flange of the vacuum chamber 15. The bellows 26 maintains the pressure-reducing state similar to the container 15. One end of the plate 25 is connected to a linear motion axis 27 through the bellows 26. The linear motion axis 27 can move the plate 25 and the bellows 26 in the vertical direction by turning the knob 29 connected to the fixing tool 28.

A conceptual view in FIG. 17 illustrates the superconducting filter device 700 in which the drive tool is separated from the low-loss dielectric member 13 by moving the plate 25 upward. In the device in FIG. 17, the plate 25 fixes the right driving tool and the right linear motion device indicated by attaching a symbol A, as well as the left driving tool and the left linear motion device indicated by attaching a symbol B, whereby both drive tools move together. In the case where the plate 25 is separated into a plate 25A and a plate 25B, each plate can independently connect and separate the drive tool and the low-loss dielectric member 13 to and from each other. In the embodiment, the container 15 and the bellows 26 can maintain the pressure-reducing state, so that the variation in the high-frequency characteristic due to heat transfer or vibration after the adjustment is reduced. The support rod 27 that is a member for linearly moving the drive tool does not penetrate the vacuum wall of the vacuum chamber 15, whereby vacuum state is enhanced. Even when air is temporarily exhausted by a pump not illustrated, a valve not illustrated is closed to seal the device, and then, the pump is removed, the superconducting filter device 700 can stably be operated. The adjusting method and the adjusting system are similar to those in the third and fourth embodiments.

### Tenth Embodiment

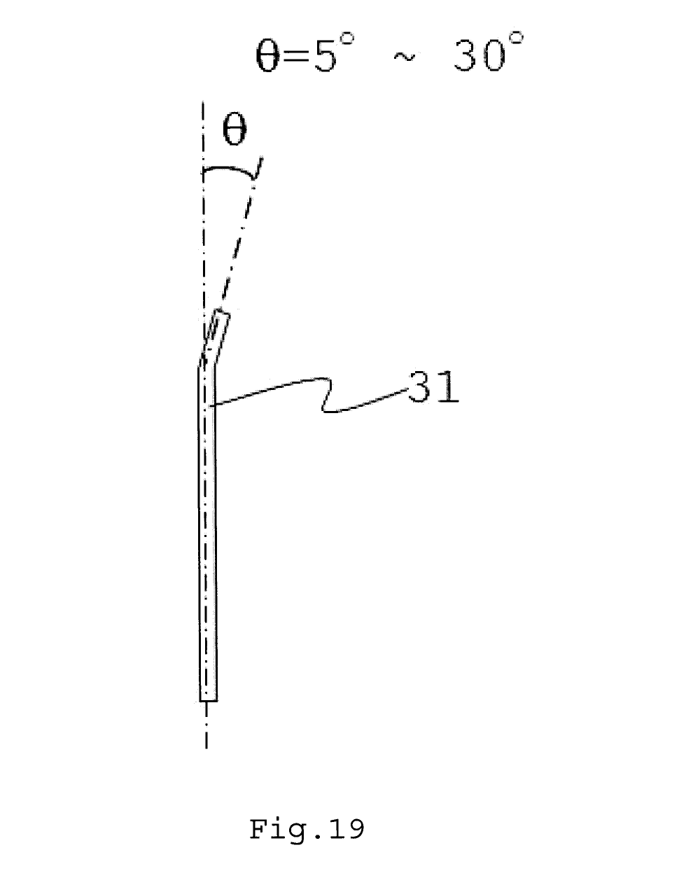

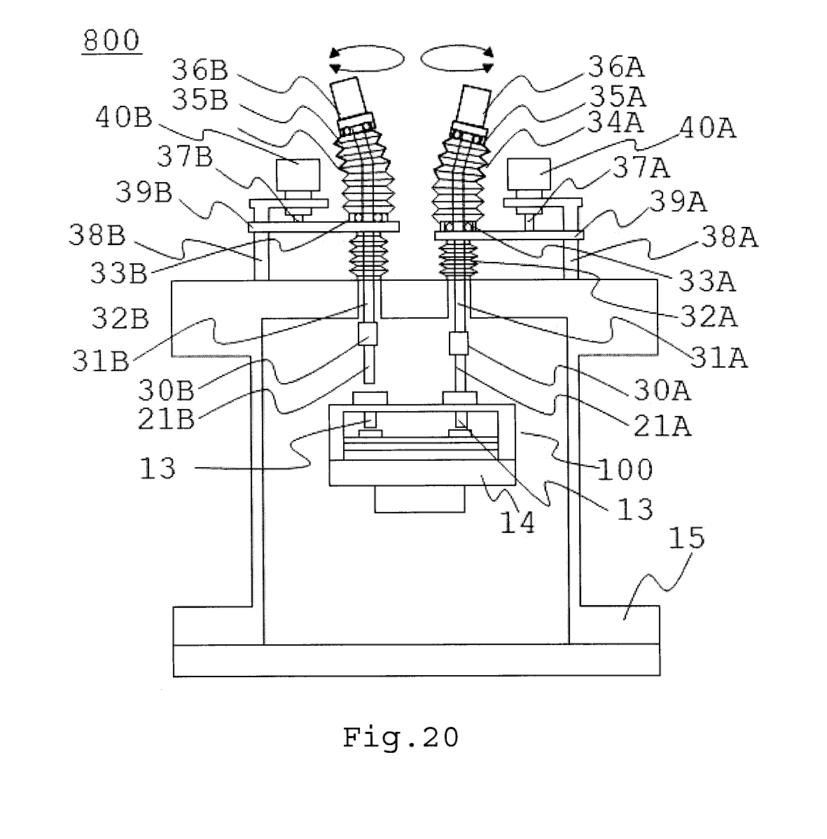

FIG. 18 is a superconducting filter device 800 in which a bellows for adjusting a height of a drive tool and the drive tool are connected to each other, and the drive tool and a dielectric member can be connected to each other or separated from each other by vertically moving the bellows. The configuration of the superconducting filter device 800 according to the tenth embodiment same as that in the ninth embodiment will not be described again. FIG. 19 is a conceptual view illustrating a tilt angle of a power transmission tool 31. FIG. 20 is a conceptual view illustrating that the left drive tool indicated by a symbol B and the left low-loss dielectric member 13 are separated from each other.

The superconducting filter device 800 illustrated in FIG. 18 includes a drive tool including a second rotation axis 21, a connection member 30, a power transmission tool 31, and a knob 36. The superconducting filter device 800 includes a linear motion device having a first bellows 32, a second bellows 34, a support rod 37, a fixing tool 38, a movable plate 39, and a knob 40. The second rotation axis 21 and the power transmission tool 31 are connected by the connection member 30. One opening of the first bellows 32 is welded to cover a through-hole on a top flange of the container 15. The other opening of the first bellows 32 is welded to the movable plate 39. Both of the openings of the first bellows 32 are welded, whereby the first bellows 32 can keep vacuum state. A hole through which the power transmission tool 31 can be rotated and moved in the vertical direction is formed on the movable plate 39. A first rotation auxiliary member 33 is provided on the surface of the movable plate 39 opposite to the surface where the first bellows 32 is welded. The first rotation auxiliary member 33 is also connected to an opening of the second bellows 34. The other opening of the second bellows 34 is connected to a second rotation auxiliary member 35. The power transmission tool 31 is not straight, but bent. The power transmission tool 31 passes through the first bellows 32, the movable plate 39, the first rotation auxiliary member 33, the second bellows 34, and the second rotation auxiliary member 35. The power transmission tool 31 is connected to the knob 36 in the second rotation auxiliary member 35. When a precession motion is caused on the knob 36 and the bellows 32 and 34, the end of the power transmission tool 31 in contact with the low-loss dielectric member 13 can be rotated.

The first bellows 32, the movable plate 39, the first rotation auxiliary member 33, the second bellows 34, the second rotation auxiliary member 35, and the knob 36 have vacuum state, like the container 15. They are welded or sealed in order to keep the pressure-reducing state similar to the state in the container 15. The movable plate 39 is mounted to be movable on a support rod of the fixing tool 38. The fixing tool 38 includes the support rod 37 and the knob 40 that can move the movable plate 39 in the vertical direction. The exposed length of the support rod 37 can be adjusted by turning the knob 40, whereby the height of the movable plate 39 can be adjusted. As illustrated in the conceptual view in FIG. 20, the drive tool can be connected to or separated from the low-loss dielectric member 13 by adjusting the height of the movable plate 39. In the conceptual view in FIG. 20, the left drive tool indicated by the symbol B moves upward. The knob 40 can independently adjust the right drive tool indicated by the symbol A and the left drive tool indicated by the symbol B respectively.

The container 15, the first bellows 32, and the second bellows 34 can form an elastically deformable vacuum wall that can maintain a pressure-reducing state of 10² Pa or less, preferably 10⁻⁴ Pa or less. The rotation auxiliary member 37 is a bearing or a sleeve made of a material having small friction coefficient, such as Teflon. The power transmission tool 31 is bent at an angle of about 5 degrees to 30 degrees with respect to a straight line in the vicinity of one end as illustrated in the conceptual view in FIG. 19.

The power transmission tool 31 does not penetrate the vacuum wall, whereby vacuum state is enhanced. Even when air is temporarily exhausted by a pump not illustrated, a valve not illustrated is closed to seal the device, and then, the pump is removed, the superconducting filter device 800 can stably be operated. When the filter device includes plural low-loss dielectric members 13, plural first bellows 32 and the plural second bellows 34 may be connected to one movable plate 39, in order to connect the left and right drive tools illustrated in the figure together to or from the low-loss dielectric member 13. In this case, much heat is transferred during the adjustment, but the number of the linear motion devices can be reduced, whereby space saving can be realized with a simple configuration. On the other hand, when a linear motion device is independently provided to each of the plural low-loss dielectric members 13, a large space is needed, but the heat transfer during the adjustment is reduced. As described above, a high-frequency characteristic is adjusted by causing the precession motion on the knob 36, and after the adjustment, the movable plate 39 is linearly moved to separate the drive tool from the low-loss dielectric member 13. This configuration reduces the variation in the high-frequency characteristic due to heat transfer or vibration after the adjustment. The adjusting method and the adjusting system are similar to those in the third and fourth embodiments.

### EXAMPLE 1

Example 1 describes an experimental example in which the superconducting filter device illustrated in the conceptual view in FIG. 13 is implemented.

A bandpass filter including a superconducting element, which is formed on a sapphire substrate by processing a YBa₂Cu₃Oₓ oxide superconducting film with a lithography technique, and a ground plane made of a similar superconducting film is prepared, and this bandpass filter is fixed on a support member made of Cu. An outer container made of Cu is fixed on the support member to cover the superconducting element. A dielectric member made of sintered alumina for adjusting a frequency characteristic of the superconducting element is mounted to the outer container. These components are mounted on a cold head that is cooled to 77 K or less by an unillustrated freezer, and they are put in an vacuum container. Pressure in the vacuum container is reduced by an exhaust device not illustrated to cause vacuum insulation, and then, the components are cooled to 70 K. The dielectric member is mounted to a male screw having a small backlash, and the male screw is threaded into a female screw on the outer container. Accordingly, the distance between the superconducting element and the dielectric member is changed by turning the male screw, whereby the high-frequency characteristic of the superconducting element is adjusted. After the tip end of the male screw is meshed with the rotation axis of the drive tool, a user turns an internal magnet by rotating an external magnet, while checking a passing waveform and reflection waveform of an unillustrated network analyzer, thereby rotating the rotation axis via the gear to adjust the position of the dielectric member. In the bandpass filter with four stages having a central frequency of 9 GHz illustrated in FIG. 1, each of four superconducting elements is adjusted, whereby a sharp-cut filter characteristic having an insertion loss of 0.1 dB or less and reflection of −20 dB or less is obtained. Thereafter, the external magnet is lifted and fixed. Thus, the superconducting filter device and the adjusting method that can prevent a variation in the high-frequency characteristic due to heat transfer or vibration can be provided.

In the specification, some elements are represented by an element symbol.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A superconducting filter device comprising:
a high-frequency filter including a superconducting element, and a dielectric member; and
a drive tool configured to adjust a distance between the superconducting element and the dielectric member, wherein
the dielectric member and the drive tool take both a connection state and a separation state.

2. The device according to claim 1, comprising:
an vacuum chamber, wherein
the high-frequency filter, the dielectric member, and the drive tool are stored in an vacuum space in the vacuum chamber, and
a drive source that drives the drive tool is provided outside the vacuum chamber.

3. The device according to claim 1, wherein the drive source has power for rotating the drive tool.

4. The device according to claim 1, wherein the drive source is not in contact with the drive tool.

5. The device according to claim 1, wherein the drive source has power for changing the connection state and the separation state.

6. The device according to claim 1, wherein the drive tool is not in contact with the vacuum chamber.

7. A superconducting filter device comprising:
a high-frequency filter including a superconducting element, and a dielectric member;
a drive tool configured to adjust a distance between the superconducting element and the dielectric member;
an vacuum chamber that stores the high-frequency filter and the drive tool in an vacuum space; and
a drive source that drives the drive tool and that is provided outside the vacuum chamber, wherein
the drive tool and the vacuum chamber are not in contact with each other.

8. A superconducting filter adjusting method for a superconducting filter device including a high-frequency filter, which has a superconducting element and a dielectric member configured to adjust a filter characteristic of the superconducting element, and a drive tool that adjusts a distance between the superconducting element and the dielectric member, the method comprising:
a step of cooling the superconducting element to bring the superconducting element into a superconducting state;
a step of adjusting the distance between the dielectric member connected to the drive tool and the superconducting element;
a step of evaluating a filter characteristic of the high-frequency filter; and
a step of separating the dielectric member and the drive tool from each other.

9. The method according to claim 8, wherein
the high-frequency filter and the drive tool are stored in an air container in a vacuum state, and
one or more steps selected from the step of adjusting the distance between the superconducting element and the dielectric member, the step of connecting the dielectric member and the drive tool, and the step of separating the dielectric member and the drive tool from each other is executed from the outside of the vacuum chamber with the drive tool and the vacuum chamber not in contact with each other.

10. The method according to claim 8, further comprising after the step of separating the dielectric member and the drive tool from each other:
a step of connecting the dielectric member and the drive tool to each other;
a step of re-adjusting the distance between the dielectric member connected to the drive tool and the superconducting element;
a step of re-evaluating the filter characteristic of the high-frequency filter; and
a step of separating again the dielectric member and the drive tool from each other.
